(19) United States
(12) Patent Application Publication
(10) Pub. No.: US 2026/0293601 A1
(43) Pub. Date: Sep. 24, 2026

(54) ELECTROSTATIC CHUCK WITH DYNAMIC VOLTAGE CONTROLLER

(71) Applicant: Axcelis Technologies, Inc., Beverly, MA (US)

(72) Inventors: Robert Fryer, Nottingham, NH (US); Wade Krull, South Hamilton, MA (US); Christopher Lamontagne, Georgetown, MA (US); David Burtner, Belmont, MA (US); Sean Jones, Haverhill, MA (US); Kevin Wenzel, Belmont, MA (US)

(21) Appl. No.: 19/574,842

(22) Filed: Mar. 23, 2026

Related U.S. Application Data
(60) Provisional application No. 63/776,544, filed on Mar. 24, 2025.

(51) Int. Cl. H10P 72/72; H10P 72/00

(52) U.S. Cl. CPC H10P 72/722; H10P 72/0616

(57) ABSTRACT

In some embodiments, the present disclosure relates to a method. The method includes placing a semiconductor workpiece on a platen. One or more electrodes are embedded within the platen. One or more electrode driving signals are applied to the one or more electrodes. A warpage of the semiconductor workpiece is monitored during application of the one or more electrode driving signals. Voltages of the one or more electrode driving signals are dynamically adjusted based on the warpage.

### REFERENCE TO RELATED APPLICATIONS

This application claims the benefit of U.S. Provisional Application Ser. No. 63/776,544 filed Mar. 24, 2025, entitled, “DECLAMP ROUTINES TO MITIGATE JUMPING WAFERS”, the contents of which are herein incorporated by reference in their entirety.

### BACKGROUND

In the semiconductor industry, a wafer chuck is a plate on which wafers are securely mounted to hold the wafer flat and stationary during wafer processing applications. Different types of wafer chucks may use vacuum forces, electrostatic forces (e-chucks), and/or mechanical pins to hold wafers stationary.

### BRIEF DESCRIPTION OF THE DRAWINGS

Aspects of the present disclosure are best understood from the following detailed description when read with the accompanying figures. It is noted that various features may be, but are not necessarily, drawn to scale. In fact, the dimensions of the various features may be arbitrarily increased or reduced for clarity of discussion.

FIG. 1 illustrates some embodiments of an electrostatic chuck (ESC) system comprising a dynamic controller configured to actively control electrode voltages to reduce workpiece warpage, mitigate jumping, and/or improve declamping.

FIG. 2 illustrates some additional embodiments of an ESC system comprising a dynamic controller configured to actively control electrode voltages to reduce workpiece warpage, mitigate jumping, and/or improve declamping.

FIG. 3 illustrates a flow diagram of some embodiments of a method of dynamically controlling electrostatic chuck electrode voltages to reduce workpiece warpage, mitigate jumping, and/or improve declamping.

FIGS. 4A-4D illustrate timing diagrams showing some embodiments of exemplary electrode driving signals having a voltage that varies over time.

FIG. 5 illustrates a timing diagram showing some embodiments of an exemplary electrode driving signal and workpiece warpages over time.

FIG. 6 illustrates a timing diagram showing some additional embodiments of an exemplary electrode driving signal and workpiece warpages over time.

FIG. 7 illustrates some additional embodiments of an ESC system comprising a dynamic controller configured to actively control electrode voltages to reduce workpiece warpage, mitigate jumping, and/or improve declamping.

FIGS. 8A-8C illustrate timing diagrams showing some embodiments of ringdown sequences comprising voltage signals driven to different electrodes within a multi-phase ESC.

FIG. 9 illustrates some embodiments of an ion implantation system comprising a disclosed ESC system including a dynamic controller.

FIG. 10 illustrates some additional embodiments of an ion implantation system comprising a disclosed ESC system including a dynamic controller.

### DETAILED DESCRIPTION

The present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, or other physical or functional units shown in the drawings or described herein could also be implemented by an indirect connection or coupling. Furthermore, it is to be appreciated that functional blocks or units shown in the drawings may be implemented as separate features or components in one embodiment, and may also or alternatively be fully or partially implemented in a common feature or component in another embodiment.

An electrostatic chuck (ESC) operates by selectively applying a voltage to one or more electrodes embedded within a platen. The voltage causes the one or more electrodes to generate an electrostatic force that is configured to securely hold a semiconductor workpiece (e.g., a silicon wafer) to the platen during a semiconductor manufacturing process. It is important that ESCs are able to securely clamp a semiconductor workpiece flatly to the platen, since bowing and/or warping of the workpiece can lead to poor processing quality. For example, workpiece bowing significantly affects ion implantation by introducing stress and/or changing local crystal orientations relative to an ion beam, thereby altering ion channeling (e.g., ions travel deeper along crystal planes) and leading to non-uniform doping, inconsistent doping profiles, reduced device performance, and/or reduced yield.

It has been appreciated that the material properties of a semiconductor workpiece and/or parameters of a manufacturing process (e.g., a workpiece material, a defect density, a process temperature, etc.) can affect bowing and/or warpage of a semiconductor workpiece, making it difficult to fully (e.g., securely) clamp the workpiece to a flat surface of a platen. Even if a semiconductor workpiece is properly clamped to a platen, as parameters of the manufacturing process (e.g., ion implantation) change the bowing and/or warping may increase such that the settings of an electrostatic chuck that are sufficient to start a manufacturing process may not be sufficient to hold the workpiece flat throughout the process. Moreover, in the process of clamping a warped workpiece to a planar surface of a platen, the crystalline structure of the workpiece will store mechanical energy. Upon declamping (e.g., releasing) the workpiece from the planar surface, the workpiece will release the stored mechanical energy and cause unwanted motion and/or jumping of the workpiece. The motion and/or jumping can cause physical damage to the workpiece, lowering yield and increasing manufacturing cost.

In some embodiments, the present disclosure relates to an ESC system comprising a dynamic controller configured to actively control electrode voltages to manage regional stresses of a semiconductor workpiece and therefore reduce workpiece warpage, mitigate jumping, and/or improve declamping. The ESC system comprises a platen having an upper surface configured to receive a semiconductor workpiece. One or more electrodes are embedded within the platen. A dynamic controller is coupled to the one or more electrodes and is configured to actively adjust voltages applied to respective ones of the one or more electrodes during different times of a chucking process. In some embodiments, a workpiece warpage monitor may be configured to monitor (e.g., measure) a warpage of the semiconductor workpiece. Based upon the warpage, the dynamic controller can selectively apply different voltages to the one or more electrodes. By applying different voltages to the one or more electrodes, different forces may be applied to the semiconductor workpiece at different times, thereby enabling a semiconductor workpiece to be held flat during a manufacturing process, to mitigate jumping of the workpiece, and/or to improve declamping.

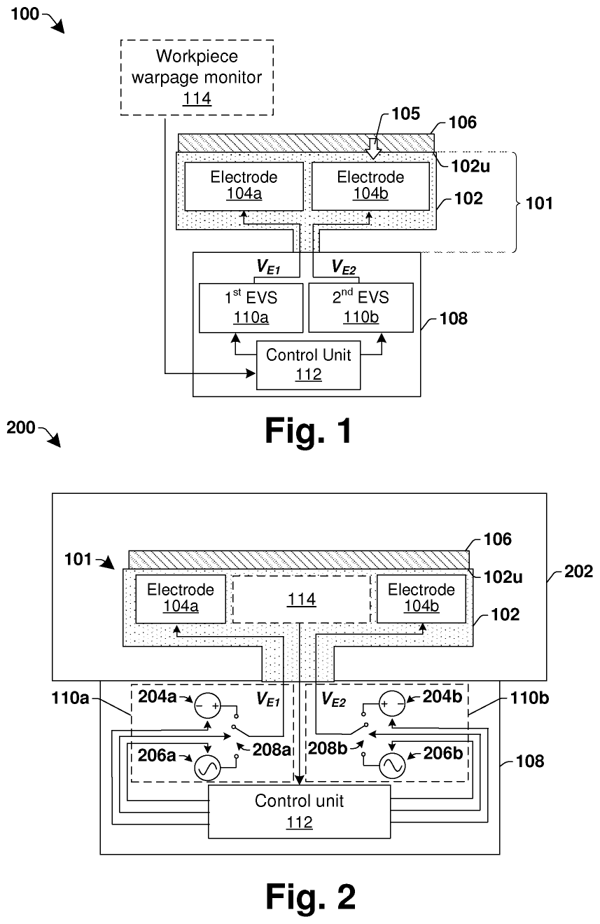

FIG. 1 illustrates some embodiments of an electrostatic chuck (ESC) system 100 comprising a controller configured to dynamically control electrode voltages to reduce workpiece warpage, mitigate jumping, and/or improve declamping.

The ESC system 100 comprises a platen 102 having an upper surface 102u configured to receive a semiconductor workpiece 106. One or more electrodes 104a-104b are embedded within the platen 102. The one or more electrodes 104a-104b are arranged within multiple spatially distinct regions of the platen 102 (e.g., at different locations along the upper surface 102u of the platen 102). In some embodiments, the one or more electrodes 104a-104b may comprise a first electrode 104a arranged within a first region and a second electrode 104b separated from the first electrode 104a and arranged within a second region. The one or more electrodes 104a-104b are configured to respectively generate an electrostatic force 105 that attracts the semiconductor workpiece 106 towards the upper surface 102u. By attracting the semiconductor workpiece 106 toward the upper surface 102u of the platen 102, the semiconductor workpiece 106 can be kept firmly in place during a semiconductor manufacturing process.

A dynamic controller 108 is coupled to the one or more electrodes 104a-104b. The dynamic controller 108 is configured to selectively apply an electrode driving signal having a variable voltage to respective ones of the one or more electrodes 104a-104b. For example, the dynamic controller 108 may apply a first electrode driving signal having a first variable voltage to a first electrode 104a and a second electrode driving signal having a second variable voltage to the second electrode 104b. In some embodiments, the variable voltage of the electrode driving signal may change over time. For example, the electrode driving signal may have a first voltage at a first time and a second voltage at a second time. In some embodiments, the electrode driving signal may comprise an intentionally controlled voltage drop over a controlled voltage path (e.g., a gradient voltage drop occurring over a non-zero time period) during declamping of the semiconductor workpiece 106.

In some embodiments, the dynamic controller 108 may comprise a control unit 112, a first variable voltage source 110a, and a second variable voltage source 110b. The first variable voltage source 110a may be coupled to the first electrode 104a and the second variable voltage source 110b may be coupled to the second electrode 104b. The control unit 112 is configured to operate the first variable voltage source 110a to apply a first electrode driving signal comprising a first variable voltage V_{E1} to the first electrode 104a and to further operate the second variable voltage source 110b to apply a second electrode driving signal comprising a second variable voltage V_{E2} to the second electrode 104b.

In some embodiments, a workpiece warpage monitor 114 may be configured to monitor (e.g., measure) a warpage of the semiconductor workpiece 106. The workpiece warpage monitor 114 may be configured to monitor the warpage by detecting a physical and/or electrical property of the semiconductor workpiece 106, which is indicative of a bow or a warp. In various embodiments, the workpiece warpage monitor 114 may comprise an optical tool (e.g., an image sensor), a capacitive sensor, a current sensor, and/or the like. Warpage data, describing the warpage of the semiconductor workpiece 106, can be provided from the workpiece warpage monitor 114 to the dynamic controller 108. Using the warpage data, the dynamic controller 108 can generate an electrode driving signal that selectively applies different voltages to the one or more electrodes 104a-104b to mitigate the warpage. In alternative embodiments, start and/or end voltages of an electrode driving signal can be set according to a calibration table constructed from ex-situ data.

By applying different electrode driving signals to the one or more electrodes 104a-104b, the dynamic controller 108 is able to apply different forces to different parts of the semiconductor workpiece 106 during different times thereby managing regional stresses of the semiconductor workpiece 106 and controlling warpage, jumping, and/or sticking of the semiconductor workpiece 106. For example, by varying the forces applied by the one or more electrodes 104a-104b the semiconductor workpiece 106 can be brought into contact with the upper surface 102u in spite of workpiece warpage. Furthermore, the semiconductor workpiece 106 can be held throughout a chucking process with a minimum force, thereby mitigating damage to the semiconductor workpiece 106. Moreover, the forces can be adjusted to mitigate jumping and/or sticking of the semiconductor workpiece 106 to the upper surface 102u, thereby avoiding potential damage to the semiconductor workpiece 106 while improving declamping and throughput of a semiconductor processing tool.

FIG. 2 illustrates some additional embodiments of an ESC system 200 comprising a dynamic controller configured to actively control electrode voltages to reduce workpiece warpage, mitigate jumping, and/or improve declamping.

The ESC system 200 comprises a processing chamber 202 including a housing. The housing has one or more sidewalls disposed between an upper surface and a lower surface. In some embodiments, the housing may comprise a metal (e.g., aluminum, iron, and/or the like), an insulator (e.g., glass filled thermoset plastics), a ceramic (e.g., alumina, silicon carbide, etc.), and/or the like. In various embodiments, the processing chamber 202 may comprise a plasma etching chamber, a photolithography chamber, a target chamber of an ion implantation system, or the like.

The housing surrounds a substrate holder 101 comprising a platen 102. The platen 102 comprises upper surface 102u configured to receive and hold the semiconductor workpiece 106 (e.g., a semiconductor wafer or a panel). One or more electrodes 104a-104b are embedded within the platen 102. For example, a first electrode 104a is embedded within a first region of the platen 102 and a second electrode 104b is embedded within a second region of the platen 102. In various embodiments, the platen 102 may include two electrodes within two regions, three electrodes within three regions, four electrodes within four regions, or any integer number of electrodes within any integer number of regions (e.g., 5, 6, etc.).

A dynamic controller 108 is configured to selectively apply one or more electrode driving signals to the one or more electrodes 104a-104b. In some embodiments, the dynamic controller 108 may comprise a control unit 112, a first variable voltage source 110a, and a second variable voltage source 110b. The first variable voltage source 110a and the second variable voltage source 110b may respectively be configured to generate an AC signal and/or a DC signal. In some embodiments, the dynamic controller 108 may comprise one or more power supplies and computer code (e.g., software and/or firmware) run on one or more processors (e.g., a CPU, a microcontroller, a GPU, and/or the like) to execute the described functionalities. In alternative embodiments, the dynamic controller 108 may comprise one or more power supplies and hardware configured to execute the described functionalities.

For example, in some embodiments the first variable voltage source 110a may comprise a first DC power supply 204a (e.g., voltage source), a first AC power supply 206a, and a first switching element 208a. The second variable voltage source 110b may comprise a second DC power supply 204b, a second AC power supply 206b, and a second switching element 208b. The control unit 112 is configured to control an amplitude of the first DC power supply 204a and the second DC power supply 204b. The control unit 112 is further configured to control an amplitude and/or a frequency of the first AC power supply 206a and the second AC power supply 206b. The control unit 112 is further configured to operate the first switching element 208a to selectively couple either the first DC power supply 204a or the first AC power supply 206a to the first electrode 104a and to further operate the second switching element 208b to selectively couple either the second DC power supply 204b or the second AC power supply 206b to the second electrode 104b. In some alternative embodiments (not shown), the first variable voltage source 110a may comprise a first DC power supply 204a (without an AC power supply and switching element) and the second variable voltage source 110b may comprise a second DC power supply 204b (without an AC power supply and switching element). In such embodiments, internal firmware may be used to operate the DC power supplies to generate an AC signal.

A workpiece warpage monitor 114 may be configured to monitor (e.g., measure) a warpage of the semiconductor workpiece 106. The workpiece warpage monitor 114 may be configured to measure the warpage as warpage data comprising Boolean logic (e.g., warped or not warped), fuzzy logic, or the like. In some embodiments, the workpiece warpage monitor 114 may comprise one or more warpage measurement electrodes embedded within the platen 102 along with the one or more electrodes 104a-104b. In such embodiments, the one or more warpage measurement electrodes may be configured to measure a capacitance and/or current associated with overlying parts of the semiconductor workpiece 106. In some alternative embodiments, the workpiece warpage monitor 114 may comprise the one or more electrodes 104a-104b. In such embodiments, the electrode driving signals and/or electronic readbacks of the electrode driving signals may be used to measure a warpage. For example, a phase difference between input and output signals may be used to measure a capacitance associated with overlying parts of the semiconductor workpiece 106. The warpage data is provided to the control unit 112. Based upon the warpage data, the control unit 112 is configured to adjust an electrode driving signal to selectively control operation of the first variable voltage source 110a and/or the second variable voltage source 110b to actively mitigate warpage of the semiconductor workpiece 106 during a chucking process.

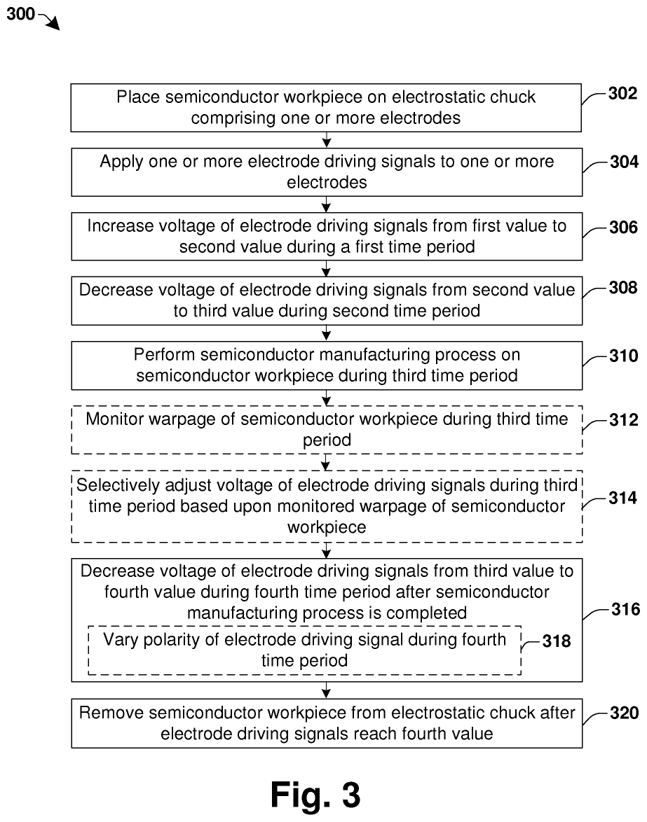

FIG. 3 illustrates a flow diagram of some embodiments of a method 300 of dynamically controlling ESC electrode voltages to reduce workpiece warpage, mitigate jumping, and/or improve declamping.

While the disclosed method 300 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 302, a semiconductor workpiece is placed on an electrostatic chuck comprising one or more electrodes. In some embodiments, the semiconductor workpiece may comprise a silicon substrate (e.g., wafer), a silicon carbide substrate (e.g., wafer), an insulating substrate (e.g., wafer), a semi-insulating substrate (e.g., wafer), a panel, or the like.

At act 304, one or more electrode driving signals are applied to the one or more electrodes. In various embodiments, the one or more electrode driving signals may comprise an AC (alternating current) signal (e.g., an AC waveform comprising a sinusoidal shape, a square wave shape, a sawtooth shape, etc.), a DC (direct current) signal, and/or a combination of AC and DC signals. It has been appreciated that over the course of a chucking process, there are conditions where an equipment setup is capable of both AC and DC operation, while other conditions necessitate DC operation and prohibit AC operation. For example, a DC signal may be applied to one or more electrodes of an electrostatic chuck when a semiconductor workpiece is held at a vertical position or when there is a high risk of dielectric breakdown, while an AC signal may be applied to the one or more electrodes when a semiconductor workpiece is held at a horizontal position.

At act 306, a voltage of the one or more electrode driving signals is increased from a first value to a second value during a first time period.

At act 308, the voltage of the one or more electrode driving signals is decreased from the second value to a third value during a second time period.

At act 310, a semiconductor manufacturing process may be performed on the semiconductor workpiece during a third time period. In some embodiments, the semiconductor manufacturing process may comprise an ion implantation process. For example, the semiconductor manufacturing process may comprise an implant and rapid thermal anneal on a silicon substrate and or a “hot implant” on a silicon carbide substrate (e.g., an ion implantation technique where a silicon carbide substrate is heated during an implantation process). In other embodiments, the semiconductor manufacturing process may comprise an etching process, a photolithography process, or the like.

At act 312, a warpage of the semiconductor workpiece is monitored during the third time period, in some embodiments. In some embodiments, the warpage may be monitored by monitoring electronic readbacks of the electrode driving signals provided to the one or more electrodes. In other embodiments, the warpage may be monitored using a metrology tool (e.g., comprising an image sensing element).

At act 314, the voltages of the one or more electrode driving signals are selectively adjusted during the third time period based upon the monitored warpage of the semiconductor workpiece, in some embodiments.

At act 316, the voltages of the one or more electrode driving signals are reduced from the third value to a fourth value (e.g., approximately zero) during a fourth time period occurring after the semiconductor manufacturing process is completed. In some embodiments, the fourth value may be equal to the third value. In some embodiments, while reducing the voltages of the one or more electrode driving signals to the fourth value, a polarity of the voltages may be varied (e.g., from a positive polarity to a negative polarity, or vice versa), at act 318.

At act 320, the semiconductor workpiece is removed from the electrostatic chuck after the voltages of the one or more electrode driving signals reach the fourth value.

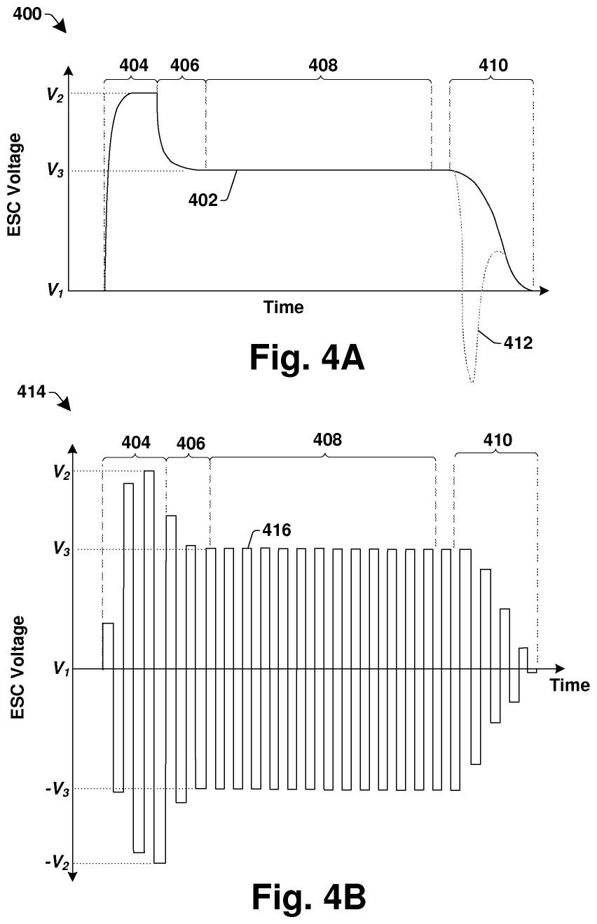

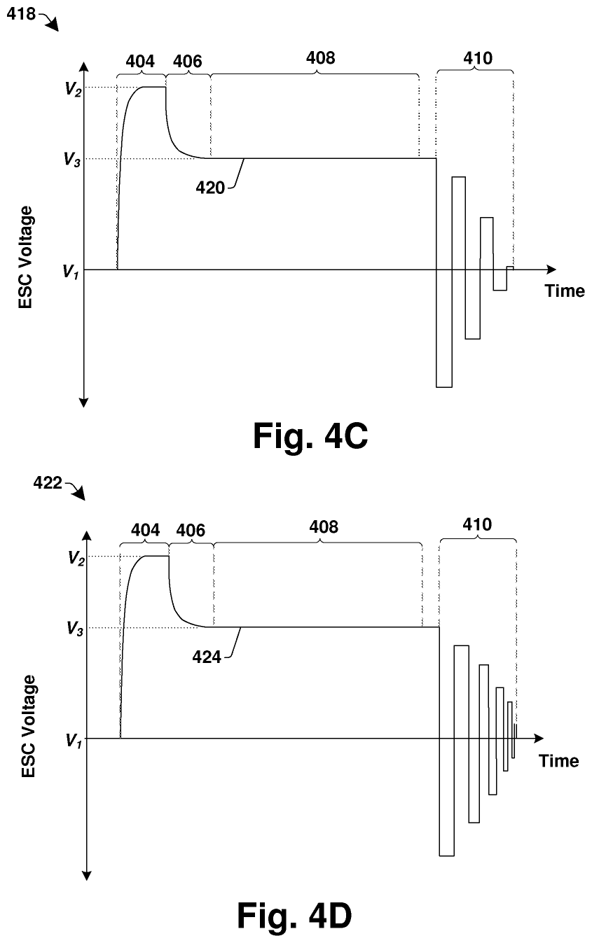

FIGS. 4A-4D illustrate some exemplary timing diagrams showing electrode driving signals that may be used by a disclosed ESC system.

FIG. 4A illustrates a timing diagram 400 showing some embodiments of an exemplary electrode driving signal comprising a DC signal applied to an electrode of a disclosed ESC system. The timing diagram 400 illustrates a voltage along a y-axis and a time along the x-axis.

As shown in timing diagram 400, over a first time period 404 (e.g., a “ringup” sequence) the electrode driving signal 402 increases from a first voltage value V₁ to a second voltage value V₂. In some embodiments, a rate at which the electrode driving signal 402 increases may vary over the first time period 404. For example, the rate at which the DC voltage increases may decrease over the first time period 404. It has been appreciated that different semiconductor workpieces may have different warpages. The larger the warpage of the semiconductor workpiece, the more difficult it may be to form a strong clamp that is able to sufficiently and safely hold a semiconductor workpiece to a platen throughout a semiconductor manufacturing process. To ensure a strong clamp between the platen and the semiconductor workpiece, the second voltage value V₂ of the electrode driving signal 402 may be selected to be greater than a known voltage value needed to flatten the workpiece, thereby ensuring that the workpiece is flattened effectively in spite of various degrees of warpage that may be present in different semiconductor workpieces. In some embodiments, the second voltage value V₂ may be in a range of between approximately 500 volts and approximately 3,000 volts, in a range of between approximately 1,000 volts and approximately 3,000 volts, greater than approximately 1,500 volts, or other similar values.

In some embodiments, the relatively large second voltage value V₂ may generate a force that is larger than what is needed to keep the semiconductor workpiece flat. Such a force may be large enough to negatively impact the semiconductor workpiece. Therefore, during a second time period 406 the electrode driving signal 402 may decrease from the second voltage value V₂ to a third voltage value V₃ that is less than the second voltage value V₂. By decreasing the electrode driving signal 402 to the third voltage value V₃, a smaller force is applied to the semiconductor workpiece thereby keeping the semiconductor workpiece flat while clamping the semiconductor workpiece less tightly to the platen. In some embodiments, the smaller force may mitigate damage to the semiconductor workpiece, decrease a build-up of charge on the semiconductor workpiece, etc. In some embodiments, the third voltage value V₃ may be in a range of between approximately 500 volts and approximately 800 volts, in a range of between approximately 500 volts and approximately 1,000 volts, or other similar values. In alternative embodiments (not shown), a force generated by the relatively large second voltage value V₂ may not negatively impact the semiconductor workpiece and the electrode driving signal may stay at the second voltage value V₂ during the second time period 406.

During a third time period 408, a manufacturing process may be performed on the semiconductor workpiece. In some embodiments, the manufacturing process may include an ion implantation process (e.g., a rapid thermal anneal implantation process on a silicon substrate, a hot implantation process on a silicon carbide substrate, etc.). In other embodiments, the manufacturing process may include an etching process (e.g., a plasma etching process), a photolithography process, and/or the like. In some embodiments, during the third time period 408 the electrode driving signal 402 may be maintained at the third voltage value V₃. In alternative embodiments, during the third time period 408 the electrode driving signal 402 may be maintained at the second voltage value V₂.

During a fourth time period 410 (e.g., a “ringdown” sequence), the electrode driving signal 402 decreases from the third voltage value V₃ (or the second voltage value V₂) to the first voltage value V₁. In some embodiments, the first voltage value V₁ may be approximately equal to zero volts. In some embodiments, the fourth time period 410 may be greater than approximately 100 milliseconds (ms), greater than 200 ms, greater than 500 ms, in a range of between approximately 500 ms and approximately 5000 ms, or other similar values. By decreasing the electrode driving signal 402 to the first voltage value V₁, a smaller force is applied to the semiconductor workpiece, thereby enabling easier declamping of the semiconductor workpiece from the platen. Furthermore, by decreasing the electrode driving signal 402 to the first voltage value V₁ over the fourth time period 410, energy stored in the semiconductor workpiece can be slowly released, thereby mitigating jumping of the semiconductor and associated damage.

In some embodiments (shown by dashed line 412), a polarity of the electrode driving signal 402 within the fourth time period 410 may be reversed (e.g., to a negative voltage value) for a short time before declamping. For example, a polarity of the electrode driving signal 402 within the fourth time period 410 may be reversed for less than 1 second, less than 500 milliseconds, or other similar values. Reversing the polarity of the electrode driving signal 402 repels the semiconductor workpiece from the platen to improve declamping. In some embodiments, reversing the polarity of the electrode driving signal 402 may cause one or more electrodes to generate a force that pushes the semiconductor workpiece away from the platen, thereby mitigating sticking of the semiconductor workpiece to the platen (e.g., due to residual charge on the semiconductor workpiece holding the workpiece to the platen) and allowing for a speed of declamping to be improved. In some embodiments, the electrode driving signal 402 may comprise a negative voltage with a maximum amplitude that is larger than the second voltage value V₂ and/or the third voltage value V₃, thereby generating a large force to aid in declamping. Improving the speed of declamping decreases a time that it takes to declamp a semiconductor workpiece and therefore can increase a throughput of an associated semiconductor processing tool.

FIG. 4B illustrates a timing diagram 414 showing some embodiments of an exemplary electrode driving signal comprising an AC signal applied to an electrode of a disclosed ESC system.

As shown in timing diagram 414, over a first time period 404 (e.g., a “ringup” sequence) the electrode driving signal 416 increases from a first voltage value V₁ to a second voltage value V₂. The AC signal has a polarity that oscillates between positive and negative values as the amplitude of the AC signal increases from the first voltage value V₁ to the second voltage value V₂. During a second time period 406, the electrode driving signal 416 decreases from the second voltage value V₂ to a third voltage value V₃. During a third time period 408, a semiconductor manufacturing process (e.g., an ion implantation process) may be performed on the semiconductor workpiece. During the third time period 408, the electrode driving signal 416 may be maintained at the third voltage value V₃. During a fourth time period 410 (e.g., a “ringdown” sequence), the electrode driving signal 416 decreases from the third voltage value V₃ to the first voltage value V₁.

FIG. 4C illustrates a timing diagram 418 showing some embodiments of an exemplary electrode driving signal comprising a combination of AC and DC signals applied to an electrode of a disclosed ESC system.

As shown in timing diagram 418, over a first time period 404 the electrode driving signal 420 comprises a DC signal that increases from a first voltage value V₁ to a second voltage value V₂. During a second time period 406, the electrode driving signal 420 comprises a DC signal that decreases from the second voltage value V₂ to a third voltage value V₃ that is less than the second voltage value V₂. During a third time period 408, a semiconductor manufacturing process (e.g., an ion implantation process) may be performed on the semiconductor workpiece. During the third time period 408, the electrode driving signal 420 may be maintained at the third voltage value V₃.

During a fourth time period 410, the electrode driving signal 420 comprises an AC signal that decreases from the third voltage value V₃ to the first voltage value V₁. It has been appreciated that applying an AC signal to an electrode typically causes less sticking between a semiconductor workpiece and a platen in comparison to applying a DC voltage to the electrode. Therefore, by changing the electrode driving signal 420 from a DC signal in the third time period 408 to an AC signal in the fourth time period 410, declamping of a semiconductor workpiece can be improved. The improved declamping can decrease a declamping time (e.g., a time that it takes for a semiconductor workpiece to relax and naturally release from the platen after voltage has been turned off) of a semiconductor workpiece.

In some embodiments, a maximum amplitude of the AC signal in the fourth time period 410 may be smaller than the second voltage value V₂ and/or the third voltage value V₃. In some embodiments (not shown), a maximum amplitude of the AC signal in the fourth time period 410 can be larger than the second voltage value V₂ and/or the third voltage value V₃. In various embodiments, the AC signal may be applied to the electrode during an entirety of the fourth time period 410 or during a part of the fourth time period. For example, in some embodiments, a DC signal may be applied to the electrode for a first part of the fourth time period 410, while an AC signal may be applied to the electrode for a second part of the fourth time period that is after the first part. Applying the AC signal to the electrode for an entirety or for a part of the fourth time period may jitter a semiconductor workpiece off of a platen to improve declamping.

FIG. 4D illustrates a timing diagram 422 showing some additional embodiments of an exemplary electrode driving signal comprising a combination of AC and DC signals applied to an electrode of a disclosed ESC system.

As shown in timing diagram 422, over a first time period 404 the electrode driving signal 424 comprises a DC signal that increases from a first voltage value V₁ to a second voltage value V₂. During a second time period 406, the electrode driving signal 424 decreases from the second voltage value V₂ to a third voltage value V₃ that is less than the second voltage value V₂. During a third time period 408, a semiconductor manufacturing process (e.g., an ion implantation process) may be performed on the semiconductor workpiece. During the third time period 408, the electrode driving signal 424 may be maintained at the third voltage value V₃.

During a fourth time period 410, the electrode driving signal 424 comprises an AC signal that decreases from the third voltage value V₃ to the first voltage value V₁. It has been appreciated that a mechanical response of a semiconductor workpiece to an AC signal can be different for different semiconductor workpieces. In some embodiments, the AC signal may have a variable frequency that sweeps over a frequency range. By having the AC signal with a variable frequency that spans a frequency range, a wide range of different frequencies can be applied to the semiconductor workpiece allowing a single waveform to cover large workpiece-to-workpiece differences. In some embodiments, the variable-frequency sweep may increase a frequency over time. In some alternative embodiments, the variable-frequency sweep may decrease a frequency over time. In yet other embodiments, the variable-frequency sweep may increase and decrease the frequency in time. Since the amplitude of the AC signal is decreasing in time, latter frequencies have less opportunity to jitter a semiconductor workpiece due to their low or near-zero amplitude. By increasing and decreasing the frequency in time, declamping of a wider range of workpieces having different mechanical responses can be improved.

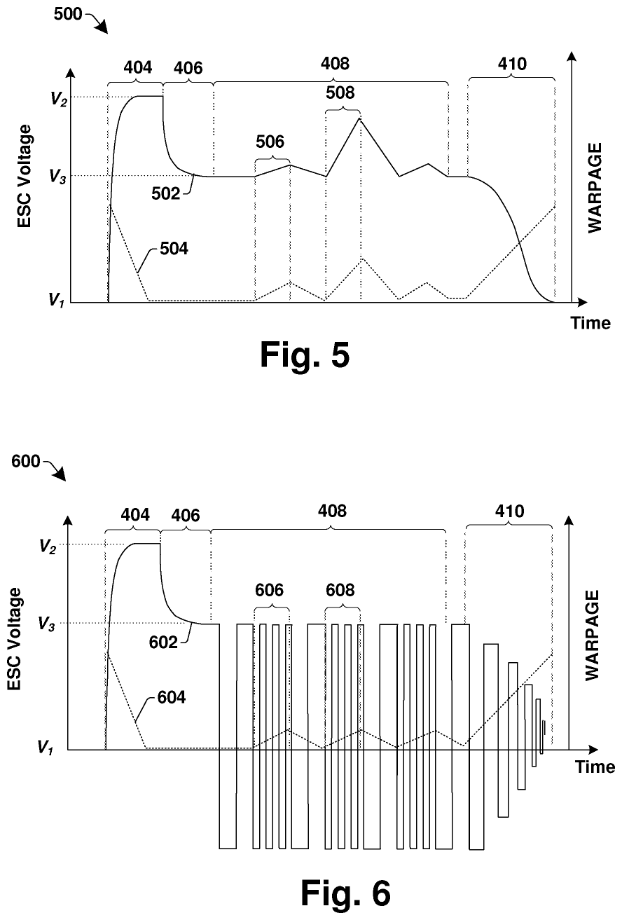

FIG. 5 illustrates a timing diagram 500 showing some embodiments of an exemplary electrode driving signal and workpiece warpages over time.

As shown in timing diagram 500, an electrode driving signal 502 comprising a DC signal is applied to an electrode during a first time period 404. Over the first time period 404, the electrode driving signal 502 increases from a first voltage value V₁ to a second voltage value V₂. During a second time period 406, the electrode driving signal 502 decreases from the second voltage value V₂ to a third voltage value V₃ that is less than the second voltage value V₂.

During a third time period 408, a semiconductor manufacturing process (e.g., an ion implantation process) may be performed on a semiconductor workpiece. During the manufacturing process, properties of the semiconductor workpiece may change, leading to changes in a warping and/or bowing of the semiconductor workpiece. For example, a bowing of a semiconductor workpiece may increase as an implant dose from an ion implantation process accumulates within the semiconductor workpiece (e.g., a silicon carbide substrate). In some embodiments, an increase in the bowing may be so extreme that a bow requires clamp voltages that would be unsafe (e.g., too high) for clamping the semiconductor workpiece at its initial bow. In such embodiments, the electrode driving signal within the third time period may be larger than the second voltage value V₂. By providing warpage feedback to a disclosed dynamic controller, the dynamic controller is able to account for changes in the bowing that occur during the semiconductor manufacturing process.

For example, timing diagram 500 shows a warpage 504 of a semiconductor workpiece as a function of time. During the first time period 404, an amplitude of the DC voltage increases and causes the warpage 504 to decrease until the warpage 504 is substantially zero (e.g., the semiconductor workpiece is substantially flat upon the platen). During the semiconductor manufacturing process, the warpage 504 of the semiconductor workpiece may increase (e.g., at time ranges 506 and/or 508). To mitigate the warpage 504, an amplitude of the electrode driving signal 502 may be increased, so as to cause the warpage 504 to decrease.

In alternative embodiments, changes in the warpage of a semiconductor workpiece caused by a manufacturing process may be controlled by changes in a frequency of an AC signal that is applied to the electrode. For example, FIG. 6 illustrates a timing diagram 600 showing some additional embodiments of an exemplary electrode driving signal 602 and warpages 604 of a semiconductor workpiece over time. As shown in timing diagram 600, the electrode driving signal 602 comprises an AC signal. During a manufacturing process, the warpage 604 of the semiconductor workpiece may increase (e.g., at time ranges 606 and/or 608). In some embodiments, to mitigate the warpage 604 a frequency of the electrode driving signal 602 may be increased (e.g., at time ranges 606 and/or 608), so as to cause the warpage 604 to decrease. In other embodiments (not shown), to mitigate the warpage 604 a frequency of the electrode driving signal 602 may be decreased (e.g., at time ranges 606 and/or 608), so as to cause the warpage 604 to decrease. In yet other embodiments (not shown), to mitigate the warpage 604 the electrode driving signal 602 may be temporarily changed to a DC signal (e.g., at time ranges 606 and/or 608), to cause the warpage 604 to decrease, and then returned to an AC signal.

It will be appreciated that the electrode driving signals disclosed herein (e.g., in FIGS. 4A-4D, 5, and 6) are merely examples and are not intended to limit the disclosure. It will be further appreciated that aspects of the different electrode driving signals disclosed herein may be combined with one another in alternative embodiments that are not illustrated. For example, a ringdown sequence of the electrode driving signal shown in FIG. 4D may replace a ringdown sequence of the electrode driving signal shown in FIG. 4B.

In some embodiments, variation of the one or more voltages of the electrode driving signal (e.g., during the first time period, the second time period, the third time period, and/or the fourth time period) may be decoupled between different regions of an electrostatic chuck (e.g., between different phases of an ESC controller). By decoupling the electrode driving signals between the different regions of an electrostatic chuck, regional semiconductor workpiece stresses can be actively managed.

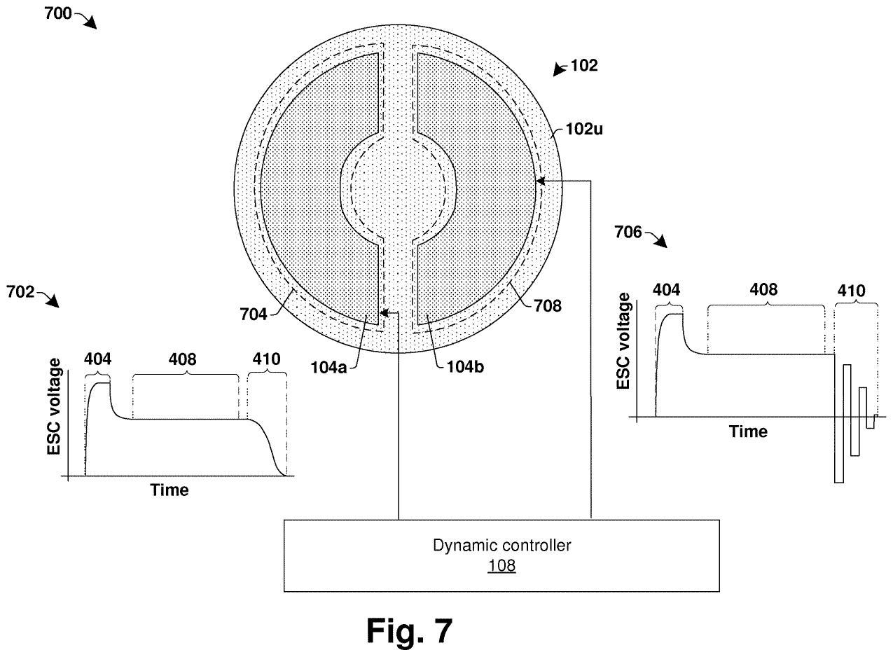

FIG. 7 illustrates some embodiments of an ESC system 700 comprising a dynamic controller configured to independently control electrode voltages applied to different regions of an ESC to reduce workpiece warpage, mitigate jumping, and/or improve declamping.

The ESC system 700 comprises a platen 102 having an upper surface 102u configured to receive and hold a semiconductor workpiece (e.g., a semiconductor wafer or a panel). One or more electrodes 104a-104b are embedded within different regions of the platen 102. In various embodiments, the one or more electrodes 104a-104b may include two electrodes, three electrodes, four electrodes, or any integer number of electrodes (e.g., 5, 6, etc.).

A dynamic controller 108 is configured to selectively apply an electrode driving signal to respective ones of the one or more electrodes 104a-104b. In some embodiments, the dynamic controller 108 is configured to apply different electrode driving signals to electrodes within different regions of the platen 102 (e.g., to apply different electrode driving signal phases to the electrodes within the different regions). For example, the dynamic controller 108 may be configured to apply a first electrode driving signal 702 to a first electrode 104a within a first region 704 and a second electrode driving signal 706 to a second electrode 104b within a second region 708. By having the one or more electrodes 104a-104b embedded within different regions of the platen 102, the dynamic controller 108 is able to control regional forces on the semiconductor workpiece to improve management of workpiece stresses so as to aid in declamping, mitigate warpage, and/or mitigate jumping.

In some embodiments, the first electrode driving signal 702 may have a ringdown sequence (e.g., within a fourth time period 410) comprising a continuous DC decay, while the second electrode driving signal 706 may have a ringdown sequence (e.g., within a fourth time period 410) comprising an arbitrary AC waveform. In some embodiments, the dynamic controller 108 may apply electrode driving signals having a same polarity to one or more electrodes 104a-104b during declamping to mitigate stress on a semiconductor workpiece.

As a semiconductor workpiece (e.g., a silicon carbide wafer) is implanted, it may heat up and store a significant amount of energy. If upon declamping, this energy is released all at once from the semiconductor workpiece, it may lead to motion and/or deformation of the semiconductor workpiece. It has been appreciated that such motion and/or deformation can be mitigated by asynchronously operating the electrode driving signals provided to the different electrodes (e.g., electrodes 104a and 104b of FIG. 7) during the ringdown sequence depending on characteristics of a semiconductor workpiece. Asynchronously operating the electrode driving signals (e.g., providing electrode driving signals having different profiles to different electrodes) during the ringdown sequence allows for accumulated energy to be released in relatively small amounts, thereby mitigating motion and/or deformation of the semiconductor workpiece.

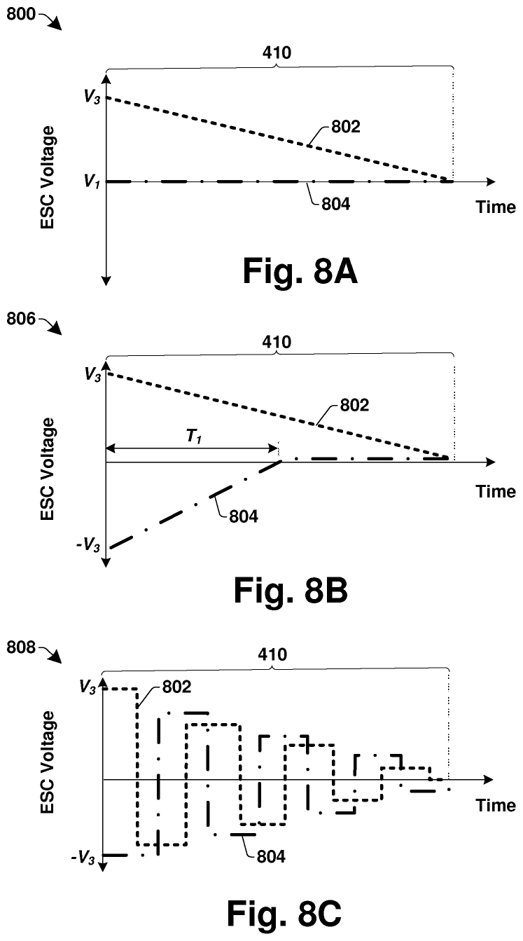

FIGS. 8A-8C illustrate timing diagrams showing some embodiments of ringdown sequences comprising voltage signals driven to different electrodes within a multi-phase ESC to mitigate motion and/or deformation of a semiconductor workpiece. It will be appreciated that the disclosed timing diagrams are examples of electrode driving signals that may be used to mitigate motion and/or deformation of a semiconductor workpiece, but that other electrode driving signals may be used in alternative embodiments.

Timing diagram 800 of FIG. 8A illustrates a fourth time period 410 (e.g., a ringdown sequence) of a first electrode driving signal 802 associated with a first electrode within a first region of an ESC and a second electrode driving signal 804 associated with a second electrode within a second region of the ESC. The first electrode driving signal 802 is a DC signal that is set to a first voltage value V₁ of approximately 0 volts at a beginning of the fourth time period 410, thereby releasing a semiconductor workpiece from the first region at a beginning of the ringdown sequence. The second electrode driving signal 804 is a DC signal that linearly decreases from a third voltage value V₃ to the first voltage value V₁ over the fourth time period 410, thereby gently releasing the semiconductor workpiece from the second region after releasing the semiconductor workpiece from the first region.

Timing diagram 806 of FIG. 8B illustrates a fourth time period 410 (e.g., a ringdown sequence) of a first electrode driving signal 802 associated with a first electrode within a first region of an ESC and a second electrode driving signal 804 associated with a second electrode within a second region of the ESC. The first electrode driving signal 802 is a DC signal that linearly decreases from a third voltage value V₃ to a first voltage value V₁ of approximately 0 volts over the fourth time period 410, thereby gently releasing the semiconductor workpiece from the first region. The second electrode driving signal 804 is a DC signal that linearly increases from a negative third voltage value −V₃ to a first voltage value V₁ over a time T₁, thereby gently pushing the semiconductor workpiece away from the second region over a time T₁.

Timing diagram 808 of FIG. 8C illustrates a ringdown sequence of a first electrode driving signal 802 associated with the first electrode and a ringdown sequence of a second electrode driving signal 804 associated with the second electrode. The first electrode driving signal 802 is an AC signal that decreases from a third voltage value V₃ to a first voltage value V₁ over the fourth time period 410, while the second electrode driving signal 804 is an AC signal that increases from a negative third voltage value −V₃ to the first voltage value V₁ over the fourth time period 410.

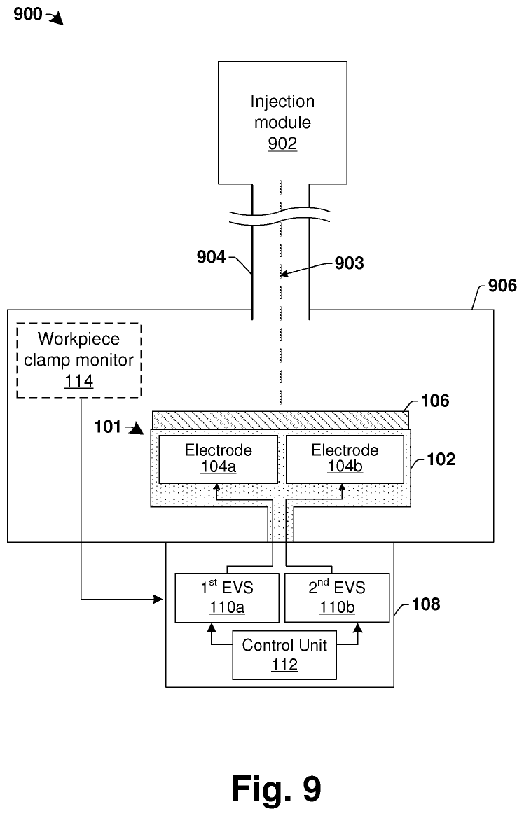

FIG. 9 illustrates some embodiments of an ion implantation system 900 comprising a disclosed ESC system comprising a dynamic controller.

The ion implantation system 900 comprises an injection module 902 in communication with a downstream target chamber 906 by way of a beam guide 904. A substrate holder 101 is arranged within the target chamber 906. The substrate holder 101 comprises a platen 102 and one or more electrodes 104a-104b embedded within the platen 102. The platen 102 comprises an upper surface configured to receive and hold a semiconductor workpiece 106. A dynamic controller 108 is in communication with the one or more electrodes 104a-104b. The dynamic controller 108 is configured to provide an electrode driving signal to the one or more electrodes 104a-104b. In some embodiments, the dynamic controller 108 may comprise a control unit 112 and one or more variable voltage sources 110a-110b respectively coupled to the one or more electrodes 104a-104b. In some embodiments, the one or more variable voltage sources 110a-110b may comprise a first variable voltage source 110a and a second variable voltage source 110b. In some embodiments, the control unit 112 is coupled to a workpiece warpage monitor 114. The workpiece warpage monitor 114 is configured to measure a bowing and/or warpage of the semiconductor workpiece 106.

During operation, the injection module 902 is configured to generate an ion beam 903. The ion beam 903 is provided along the beam guide 904 to the target chamber 906, where the ion beam 903 strikes the semiconductor workpiece 106. As an implant dose from the ion beam 903 accumulates within the semiconductor workpiece 106 over time, a bowing of the semiconductor workpiece 106 may change (e.g., increase). The workpiece warpage monitor 114 may measure warpage data that describes changes in the bowing of the semiconductor workpiece 106. The warpage data may be provided to the control unit 112. Based upon the warpage data, the control unit 112 may operate one or more of the one or more variable voltage sources 110a-110b to change a force generated by the one or more electrodes 104a-104b and to thereby mitigate the bowing of the semiconductor workpiece 106.

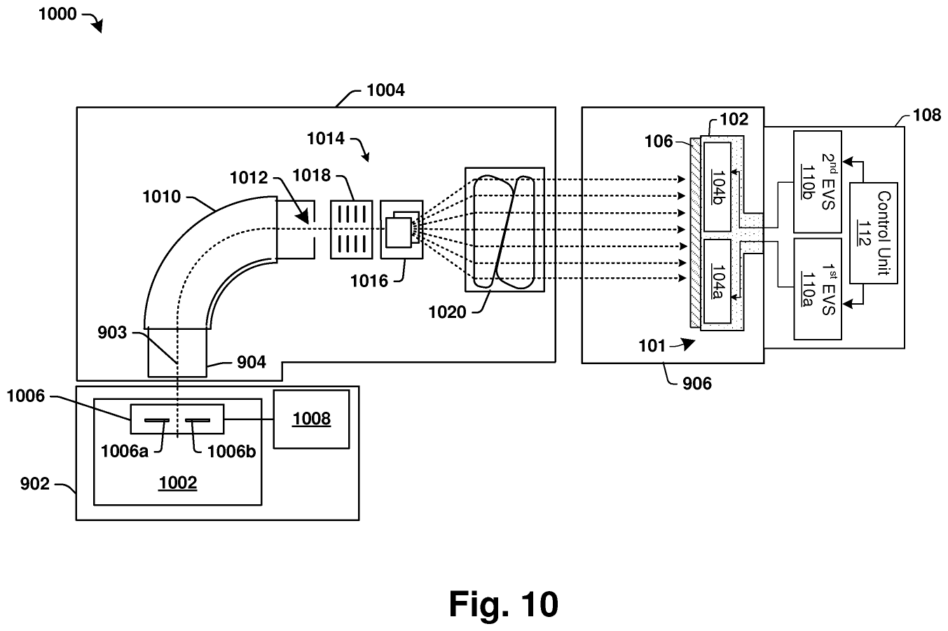

FIG. 10 illustrates some additional embodiments of an ion implantation system 1000 comprising a disclosed ESC system comprising a dynamic controller.

The ion implantation system 1000 comprises an injection module 902, a beamline assembly 1004, and a target chamber 906. The injection module 902 comprises an ion source 1002 configured to generate ions. In some embodiments, the ions are controllably extracted as an ion beam 903 through an aperture or slit in the plasma chamber via an ion extraction assembly 1006. The ion extraction assembly 1006 comprises a plurality of extraction and/or suppression electrodes, 1006a and 1006b. In some embodiments, the ion extraction assembly 1006 may comprise an extraction power supply 1008 that provides a bias voltage to the extraction and/or suppression electrodes, 1006a and 1006b.

The beamline assembly 1004 has a beam guide 904. In some embodiments, the beamline assembly 1004 may further comprise a mass analyzer 1010 configured to generate a magnetic field. As the ion beam 903 enters the mass analyzer 1010, the ions within the ion beam 903 are bent by the magnetic field to have a radius of curvature inversely proportional to their mass. Ions having too great or too small a charge-to-mass ratio are deflected into side walls of the beam guide 904. In this manner, the mass analyzer 1010 allows those ions in the ion beam 903 which have the desired charge-to-mass ratio to pass there-through and exit through a resolving aperture 1012 comprising an opening located at the end of the mass analyzer 1010. In other embodiments, the source material may be sufficiently pure to allow implantation without mass analysis (i.e., so that the beamline assembly 1004 does not comprise a mass analyzer 1010).

In various embodiments, the ion implantation system 1000 may comprise additional components. For example, the ion implantation system 1000 may comprise a magnetic scanning system 1014 located downstream of the mass analyzer 1010. The magnetic scanning system 1014 may include a magnetic scanning element 1016 and a magnetic or electrostatic focusing element 1018. A scanned beam is passed through a parallelizer 1020, which comprises two dipole magnets that cause the scanned beam to alter its path such that the scanned beam travels parallel to a beam axis regardless of the scan angle. The target chamber 906 then receives the scanned beam which is directed toward a semiconductor workpiece 106 held by a disclosed substrate holder 101 having one or more electrodes 104a-104b coupled to a dynamic controller 108 configured to actively control electrode voltages to reduce workpiece warpage, mitigate jumping, and/or improve declamping.

It will be appreciated that the ion implantation systems provided herein (e.g., 900 and/or 1000) are presented for illustrative purposes and it is appreciated that aspects of the invention are not limited to the described ion implantation systems and that other suitable ion implantation systems can also be employed.

Accordingly, the present disclosure relates to an electrostatic chuck system comprising a dynamic controller configured to actively control electrode voltages to reduce workpiece warpage, mitigate jumping, and/or improve declamping.

In some embodiments, the present disclosure relates to a method. The method includes placing a semiconductor workpiece on a platen, one or more electrodes being embedded within the platen; applying one or more electrode driving signals to the one or more electrodes; monitoring a warpage of the semiconductor workpiece during application of the one or more electrode driving signals; and dynamically adjusting voltages of the one or more electrode driving signals based on the warpage.

In other embodiments, the present disclosure relates to an apparatus. The apparatus includes a platen having an upper surface configured to receive a semiconductor workpiece; a plurality of electrodes embedded within a plurality of different regions of the platen; a dynamic controller coupled to the plurality of electrodes; and the dynamic controller being configured to independently apply separate electrode driving signals to respective ones of the plurality of electrodes, one or more of voltages and frequencies of the electrode driving signals varying over time.

In yet other embodiments, the present disclosure relates to an apparatus. The apparatus includes a platen having an upper surface configured to receive a semiconductor workpiece; one or more electrodes embedded within the platen; a dynamic controller coupled to the one or more electrodes, the dynamic controller being configured to apply one or more electrode driving signals to respective ones of the one or more electrodes; and the one or more electrode driving signals respectively including voltages that increase from a first voltage value to a second voltage value during a first time period, decrease from the second voltage value to a third voltage value during a second time period that is after the first time period, and decrease from the third voltage value to a fourth voltage value along a controlled voltage path over a third time period.

Although the disclosure has been shown and described with respect to certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. A method, comprising:
placing a semiconductor workpiece on a platen, wherein one or more electrodes are embedded within the platen;
applying one or more electrode driving signals to the one or more electrodes;
monitoring a warpage of the semiconductor workpiece during application of the one or more electrode driving signals; and
dynamically adjusting voltages of the one or more electrode driving signals based on the warpage.

2. The method of claim 1, further comprising:
increasing the voltages of the one or more electrode driving signals from a first voltage value to a second voltage value during a first time period, and
decreasing the voltages of the one or more electrode driving signals from the second voltage value to a third voltage value during a second time period that is after the first time period.

3. The method of claim 2, further comprising:
reducing the voltages of the one or more electrode driving signals from the third voltage value to a fourth voltage value over a third time period; and
removing the semiconductor workpiece from the platen after the one or more electrode driving signals reach the fourth voltage value.

4. The method of claim 1, further comprising:
performing a semiconductor manufacturing process on the semiconductor workpiece during a first time period, wherein the voltages of the one or more electrode driving signals have a first voltage value during the first time period; and
reducing the voltages of the one or more electrode driving signals from the first voltage value to a second voltage value over a second time period occurring after the semiconductor manufacturing process is completed.

5. The method of claim 4, wherein the second time period is between approximately 500 milliseconds and approximately 5000 milliseconds.

6. The method of claim 4, wherein the one or more electrode driving signals respectively comprise a direct current (DC) signal within the first time period and an alternating current (AC) signal within the second time period.

7. The method of claim 4, wherein the one or more electrode driving signals within the second time period include an AC signal having a variable-frequency sweep.

8. The method of claim 1, wherein the one or more electrode driving signals respectively comprise one or more of a DC signal and an AC signal.

9. The method of claim 1,
wherein the one or more electrodes are embedded within the platen in multiple spatially distinct regions, and
wherein the voltages of the one or more electrode driving signals associated with the one or more electrodes in the spatially distinct regions are independently controlled.

10. The method of claim 1, further comprising:
applying a first electrode driving signal to a first electrode of the one or more electrodes, wherein the first electrode driving signal has a first profile in a ringdown sequence of the first electrode driving signal; and
applying a second electrode driving signal to a second electrode of the one or more electrodes, wherein the second electrode driving signal has a second profile in a ringdown sequence of the second electrode driving signal, the second profile being different than the first profile.

11. An apparatus, comprising:
a platen having an upper surface configured to receive a semiconductor workpiece;
a plurality of electrodes embedded within a plurality of different regions of the platen;
a dynamic controller coupled to the plurality of electrodes; and
wherein the dynamic controller is configured to independently apply separate electrode driving signals to respective ones of the plurality of electrodes, one or more of voltages and frequencies of the electrode driving signals varying over time.

12. The apparatus of claim 11, wherein the dynamic controller comprises:
a first variable voltage source coupled to a first electrode of the plurality of electrodes; and
a second variable voltage source coupled to a second electrode of the plurality of electrodes.

13. The apparatus of claim 11, further comprising:
a workpiece warpage monitor configured to monitor a warpage of the semiconductor workpiece; and
wherein the dynamic controller is configured to vary the voltages of the electrode driving signals to mitigate the warpage.

14. The apparatus of claim 11, wherein the dynamic controller is configured to:
increase the voltages of the electrode driving signals from a first voltage value to a second voltage value during a first time period;
decrease the voltages of the electrode driving signals from the second voltage value to a third voltage value during a second time period that is after the first time period; and
reduce the voltages of the electrode driving signals from the third voltage value to a fourth voltage value over a third time period.

15. The apparatus of claim 14, wherein the electrode driving signals respectively comprise a direct current (DC) signal within the second time period and an alternating current (AC) signal within the third time period.

16. An apparatus, comprising:
a platen having an upper surface configured to receive a semiconductor workpiece;
one or more electrodes embedded within the platen;
a dynamic controller coupled to the one or more electrodes, wherein the dynamic controller is configured to apply one or more electrode driving signals to respective ones of the one or more electrodes; and
wherein the one or more electrode driving signals respectively comprise voltages that increase from a first voltage value to a second voltage value during a first time period, decrease from the second voltage value to a third voltage value during a second time period that is after the first time period, and decrease from the third voltage value to a fourth voltage value along a controlled voltage path over a third time period.

17. The apparatus of claim 16, wherein the dynamic controller comprises:
a first variable voltage source coupled to a first electrode of the one or more electrodes, wherein the first variable voltage source includes a first AC power supply and a first DC power supply; and
a second variable voltage source coupled to a second electrode of the one or more electrodes, wherein the second variable voltage source includes a second AC power supply and a second DC power supply.

18. The apparatus of claim 16, wherein the one or more electrode driving signals respectively comprise one or more of a direct current (DC) signal and an alternating current (AC) signal.

19. The apparatus of claim 16, further comprising:
a workpiece warpage monitor configured to monitoring a warpage of the semiconductor workpiece, wherein the dynamic controller is configured to generate the one or more electrode driving signals using the warpage of the semiconductor workpiece.

20. The apparatus of claim 19, wherein the workpiece warpage monitor comprises the one or more electrodes.
